(19) United States
(12) Patent Application Publication
(10) Pub. No.: US 2011/0177260 A1
(43) Pub. Date: Jul. 21, 2011

(54) PLASMA CVD DEVICE, METHOD FOR DEPOSITING THIN FILM, AND METHOD FOR PRODUCING MAGNETIC RECORDING MEDIUM

(76) Inventors: Yuuji Honda, Nagareyama-shi (JP); Masafumi Tanaka, Nagareyama-shi (JP); Masahisa Oikawa, Nagareyama-shi (JP)

(21) Appl. No.: 13/001,062

(22) PCT Filed: Jun. 30, 2009
(86) PCT No.: PCT/JP2009/061918

§ 371 Date: Mar. 4, 2011

(30) Foreign Application Priority Data
Jul. 1, 2008 (JP) 2008-172489

(51) Int. Cl. G11B 5/84; C23C 16/455; C23C 16/50; C23C 16/509; C23C 16/24; C23C 16/26

(52) U.S. Cl. 427/571; 118/723 E

(57) ABSTRACT

A plasma CVD device that deposits a thin film without using a filament is provided. The plasma CVD device according to the present invention includes: a chamber (1); ring-shaped ICP electrodes (17) and (18) disposed within the chamber; first high-frequency power supplies (7) and (8) electrically connected to the ICP electrodes; a gas supply mechanism that supplies a raw material gas into the chamber; an evacuation mechanism that evacuates the chamber; a disc substrate (2) disposed within the chamber so as to face the ICP electrodes; a second high-frequency power supply (6) connected to the disc substrate; an earth electrode disposed within the chamber on the opposite side of the disc substrate so as to face the ICP electrodes; and plasma walls (24) and (25) disposed within the chamber and provided so as to surround a space between the ICP electrodes and the disc substrate. Here, the plasma wall is set at a float potential.

### TECHNICAL FIELD

The present invention relates to a plasma CVD device, a method for depositing a thin film and a method for producing a magnetic recording medium. More particularly, the present invention relates to a plasma CVD device that can deposit a thin film without using a filament, a method for depositing a thin film with such a plasma CVD device and a method for producing a magnetic recording medium with such a plasma CVD device.

### BACKGROUND ART

One example of a conventional plasma CVD (chemical vapor deposition) device includes a hot filament-plasma CVD (F-pCVD) device. This plasma CVD device is a device that forms a film by turning a film-forming raw material gas into a plasma state through a discharge between a filament cathode and an anode heated within a film-forming chamber under vacuum conditions and then accelerating the plasma and causing it to collide against the surface of a substrate through a minus potential. Both of the cathode and anode are formed of metals; in particular, tantalum, which is a metal, is used for the filament cathode. With this device, it is possible to deposit a carbon (C) film and the like (for example, see patent document 1).

### RELATED ART DOCUMENT

### Patent Document

Patent document 1: Japanese Patent No. 3299721 (FIG. 1)

### DISCLOSURE OF THE INVENTION

### Problems to be Solved by the Invention

Incidentally, since, when the conventional plasma CVD device described above is used, the filament cathode is heated to 2400° C. or more to generate thermal electrons, the filament is broken in a short period of time, and its life is very short. For example, in a batch type plasma CVD device that is open to outside air every time the device is used, its filament is broken in a few batches. Even in a load lock type plasma CVD device in which a chamber is constantly brought into a vacuum state and its filament is continuously lit, the filament is broken in about five days.

Since, as described above, a problem is encountered in that the filament is likely to be broken, the filament may be broken during film formation. In this case, all products are defective. Then, in order to perform the next film formation processing, it is necessary to break a vacuum within the chamber to replace the filament; in order to sufficiently generate thermal electrons from the filament, it is necessary to perform aging processing in which the filament is lit for about one hour. Disadvantageously, the filament is likely to be broken as described above, and, when the filament is broken, it takes much time to perform the next film formation processing.

When the conventional plasma CVD device described above is used to form a DLC film or an SᵢO₂ film, it is necessary to introduce O₂ or CF₄ into the chamber to perform plasma cleaning. When this plasma cleaning is performed, the surface of the filament cathode electrode is oxidized or fluorinated, the filament is broken and the cathode electrode cannot be used. It is therefore impossible to perform the plasma cleaning using O₂ or CF₄.

The present invention has been made in view of the foregoing, and an object thereof is to provide a plasma CVD device that can deposit a thin film without using a filament, a method for depositing a thin film and a method for producing a magnetic recording medium.

### Means for Solving the Problem

To overcome the above problems, a plasma CVD device according to the present invention includes: a chamber; a ring-shaped electrode disposed within the chamber; a first high-frequency power supply electrically connected to the ring-shaped electrode; a gas supply mechanism that supplies a raw material gas into the chamber; an evacuation mechanism that evacuates the chamber; a substrate to be film-formed disposed within the chamber so as to face the ring-shaped electrode; a second high-frequency power supply or a DC power supply electrically connected to the substrate to be film-formed; an earth electrode disposed within the chamber on the opposite side of the substrate to be film-formed so as to face the ring-shaped electrode; and a plasma wall disposed within the chamber and provided so as to surround a space between the ring-shaped electrode and the substrate to be film-formed. In the plasma CVD device, the plasma wall is set at a float potential. The ring-shaped electrode is preferably an ICP electrode.

The plasma CVD device according to the present invention can further include a magnet disposed between the ring-shaped electrode and the earth electrode. The magnet is preferably ring-shaped.

In the plasma CVD device according to the present invention, the ring-shaped electrode is preferably disposed such that an inner surface of the ring-shaped electrode is substantially identical to an inner surface of the chamber adjacent to the ring-shaped electrode.

In the plasma CVD device according to the present invention, a distance between the ring-shaped electrode and the inner surface of the chamber facing an outer surface of the ring-shaped electrode is preferably 5 mm or less.

Preferably, in the plasma CVD device according to the present invention, the maximum width of a path through which the gas supply mechanism supplies gas into the chamber is 5 mm or less, and the path is set at an earth potential.

In the plasma CVD device according to the present invention, a frequency output from the second high-frequency power supply is preferably lower than a frequency output from the first high-frequency power supply.

Preferably, in the plasma CVD device according to the present invention, the first high-frequency power supply has a frequency of 1 MHz to 27 MHz, and the second high-frequency power supply has a frequency of 100 kHz to 500 kHz or less.

The plasma CVD device according to the present invention can further include heating means that heats the earth electrode. The earth electrode is preferably heated by the heating means to a temperature of 300° C. to 500° C.

In the plasma CVD device according to the present invention, the gas supplied by the gas supply mechanism into the chamber is preferably heated by the heating means.

In the plasma CVD device according to the present invention, a supply port supplied by the gas supply mechanism into the chamber is preferably ring-shaped to surround the earth electrode.

In the plasma CVD device according to the present invention, the earth electrode can be composed of a plurality of earth electrodes, and a distance between the plurality of earth electrodes facing each other can be 5 mm or less.

In a method for depositing a thin film with any one of the plasma CVD devices described above, according to the present invention, the method comprises the steps of: disposing a substrate to be film-formed within the chamber; and turning the raw material gas into a plasma state by a discharge between the ring-shaped electrode and the earth electrode to form a thin film on a surface of the substrate to be film-formed.

In the method for depositing a thin film according to the present invention, a main component of the thin film is preferably carbon or silicon.

In a method for producing a magnetic recording medium with any one of the plasma CVD devices described above, according to the present invention, the method comprises the steps of: disposing within the chamber a substrate to be film-formed obtained by forming at least a magnetic layer on a nonmagnetic substrate; turning the raw material gas into a plasma state by a discharge between the ring-shaped electrode and the earth electrode within the chamber; and accelerating the plasma and causing it to collide against a surface of the substrate to be film-formed to form a protective layer whose main component is carbon.

### Effects of the Invention

As described above, according to the present invention, it is possible to provide a plasma CVD device that can deposit a thin film without using a filament, a method for depositing a thin film and a method for producing a magnetic recording medium.

### BRIEF DESCRIPTION OF THE DRAWINGS

FIG. 1 is a schematic view showing the overall configuration of a plasma CVD device according to a first embodiment of the present invention;

FIG. 2 is an enlarged cross-sectional view of a left half of a chamber 1 shown in FIG. 1;

FIG. 3 is a perspective view of an ICP electrode (one turn coil) shown in FIG. 1;

FIG. 4 is a cross-sectional view of a gas discharge ring and a heater shown in FIG. 1;

FIG. 5 is a cross-sectional view of a magnet shown in FIG. 1;

FIG. 6 is a cross-sectional view of the ICP electrode shown in FIG. 1;

FIG. 7 is a schematic view showing the overall configuration of a plasma CVD device according to a second embodiment of the present invention;

FIG. 8 is an enlarged cross-sectional view of a hidden earth electrode shown in FIG. 7;

FIG. 9 is a schematic view illustrating a first variation;

FIG. 10 is a schematic view illustrating a second variation; and

FIG. 11 is a schematic view illustrating a third variation;

### BEST MODE FOR CARRYING OUT THE INVENTION

Embodiments of the present invention will be described below with reference to the accompanying drawings.

### First Embodiment

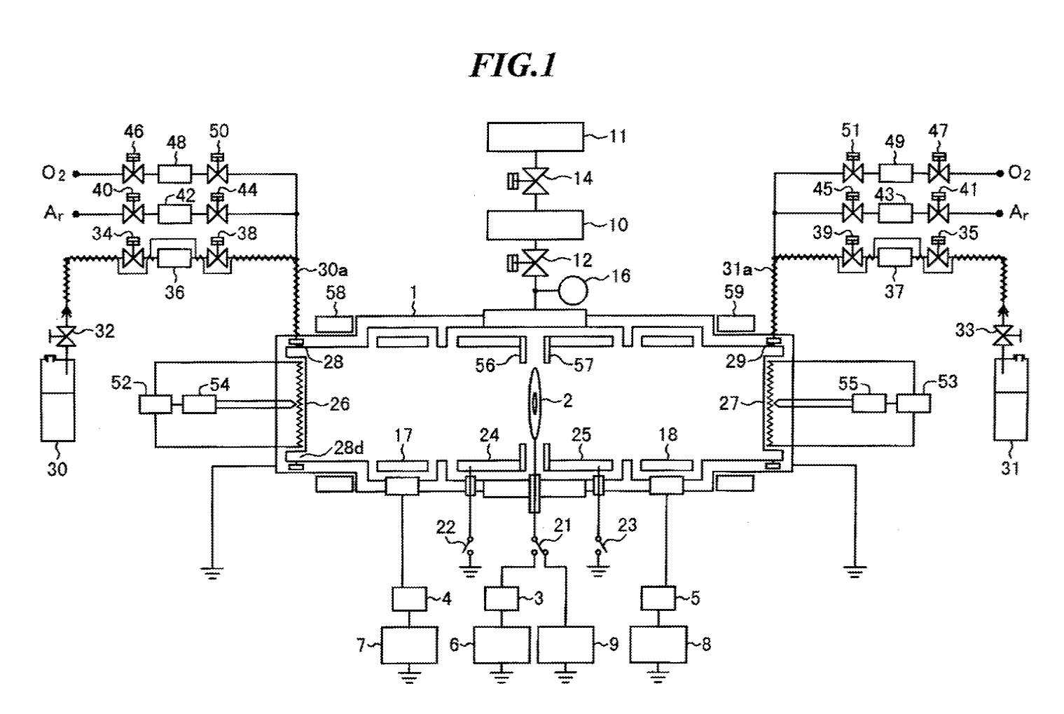

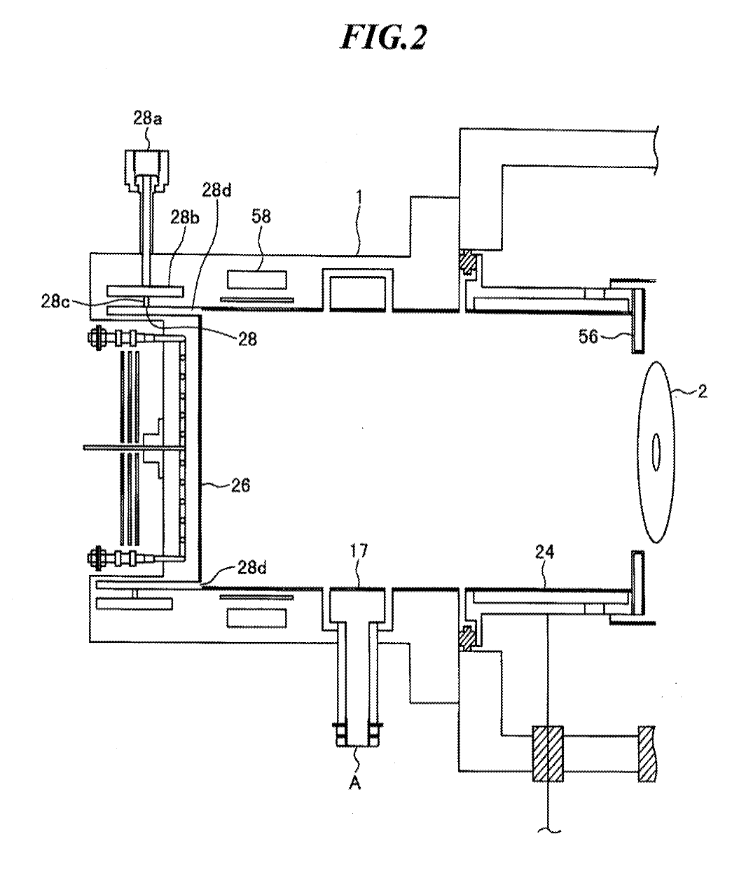

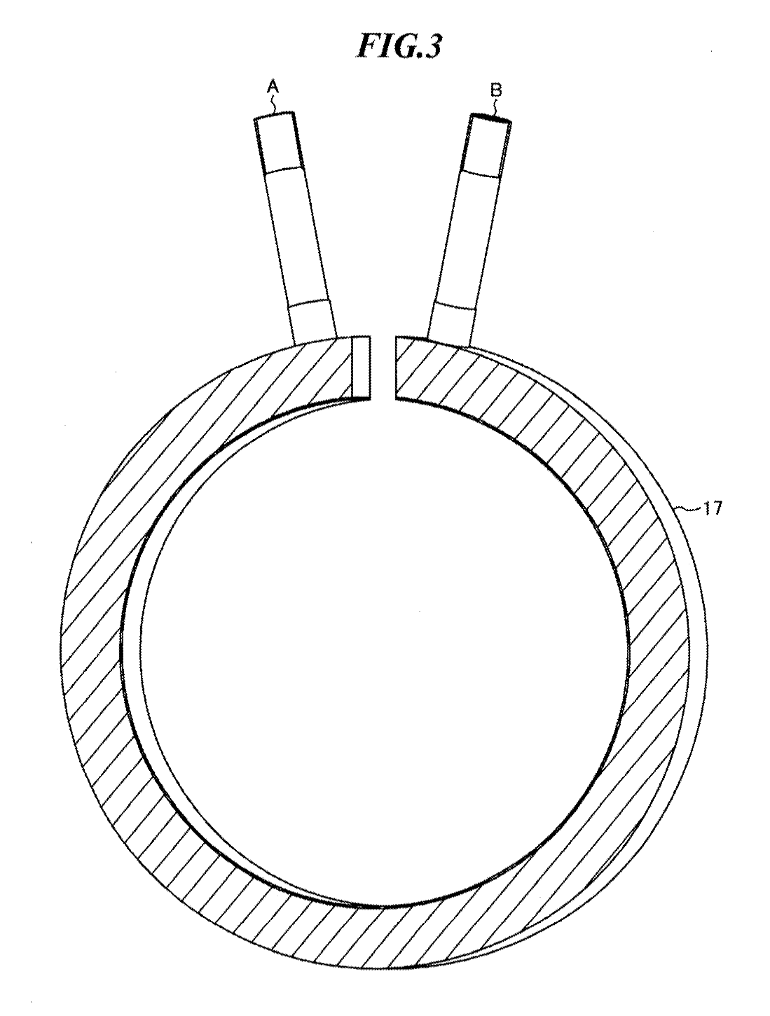

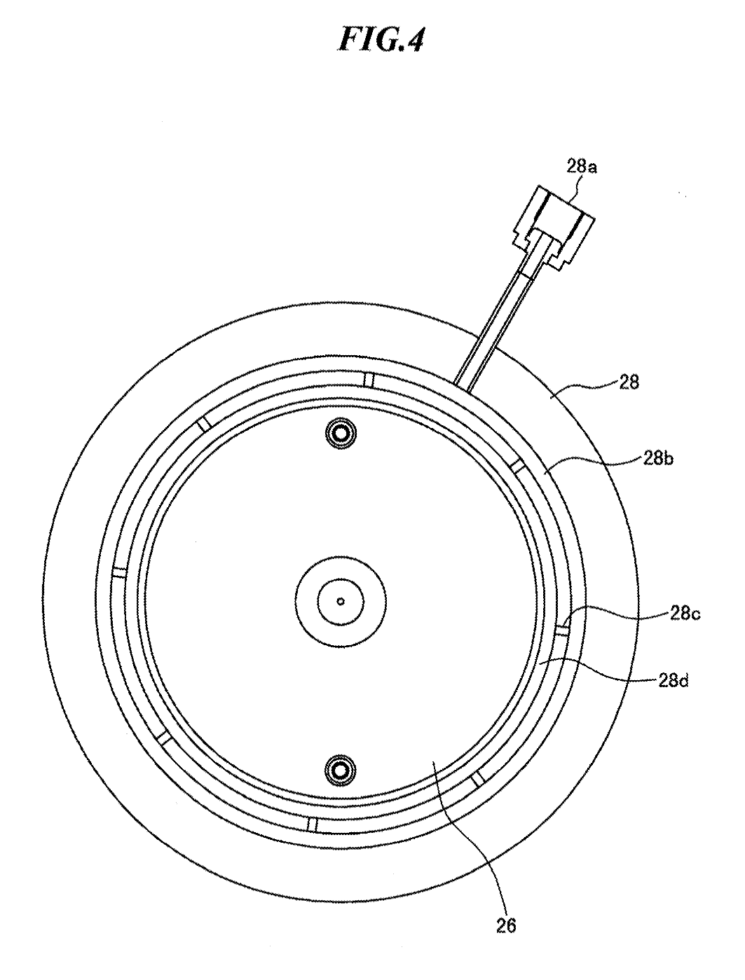

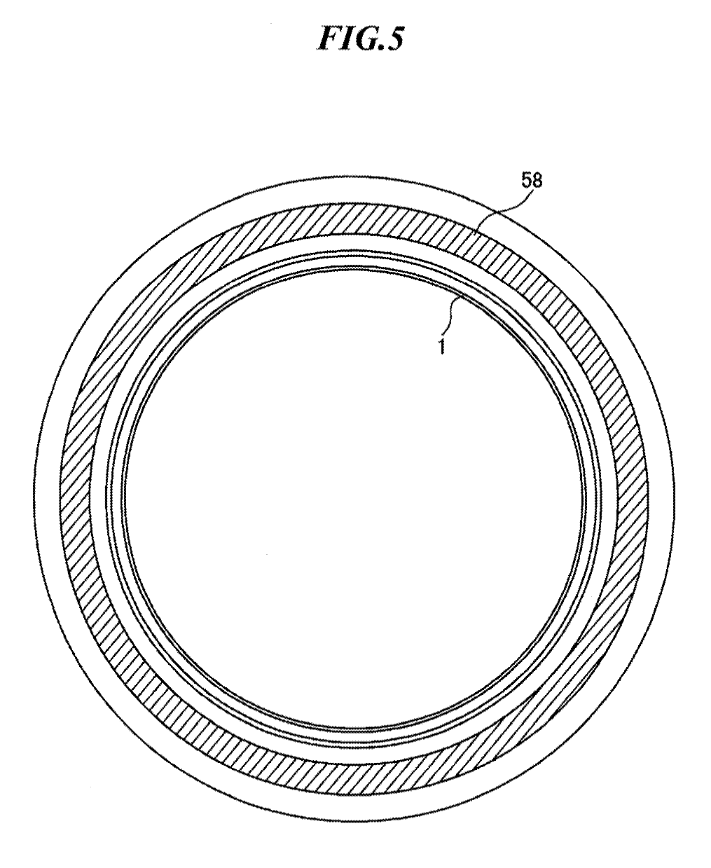

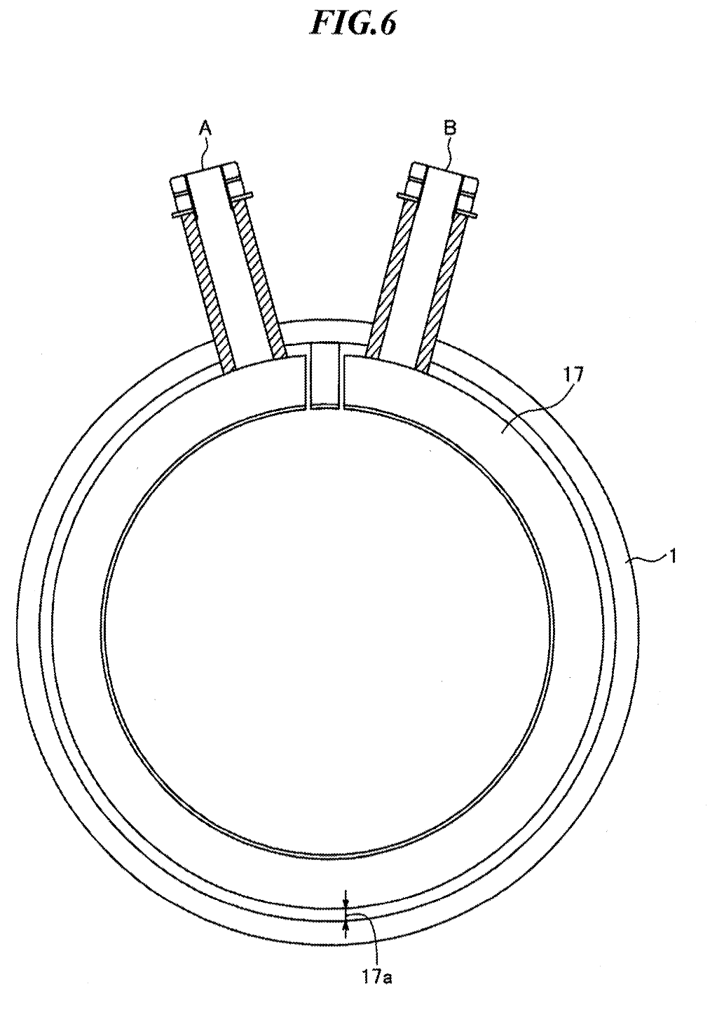

FIG. 1 is a schematic view showing the overall configuration of a plasma CVD device according to a first embodiment of the present invention. FIG. 2 is an enlarged cross-sectional view of a left half of a chamber 1 shown in FIG. 1. FIG. 3 is a perspective view of an ICP electrode (one turn coil) shown in FIG. 1. FIG. 4 is a cross-sectional view of a gas discharge ring and a heater shown in FIG. 1. FIG. 5 is a cross-sectional view of a magnet shown in FIG. 1. FIG. 6 is a cross-sectional view of the ICP electrode shown in FIG. 1.

As shown in FIG. 1, the plasma CVD device is an device that can simultaneously form films on both sides of a substrate to be film-formed (disc substrate) 2. This device has the chamber 1; the disc substrate 2 is held in the middle of the chamber 1. The plasma CVD device is left-right symmetric with respect to the disc substrate 2.

The disc substrate 2 is electrically connected to a matching box 3 through a switch 21; the disc substrate 2 is also electrically connected to a DC power supply 9 through the switch 21. The matching box 3 is electrically connected to a RF acceleration power supply 6. As the RF acceleration power supply 6, a power supply having a low frequency of 500 kHz or less is preferably used. Thus, it is possible to prevent a discharge from extending to the vicinity of the substrate to be film-formed 2. In the present embodiment, a 500 W RF acceleration power supply 6 having a frequency of 250 kHz is used.

A vacuum evacuation mechanism for vacuum-evacuating the chamber 1 is connected to the middle of the chamber 1. This vacuum evacuation mechanism includes: a turbo-molecular pump 10 connected to the chamber 1; a dry pump 11 connected to the turbo-molecular pump 10; a valve 12 disposed between the chamber 1 and the turbo-molecular pump 10; a valve 14 disposed between the turbo-molecular pump 10 and the dry pump 11; and a vacuum gauge 16 disposed between the valve 12 and the chamber 1.

As shown in FIGS. 2, 3 and 6, the plasma CVD device has a ring-shaped ICP electrode (cathode electrode) 17; this ICP electrode 17 is disposed on a side (left side of FIG. 1) facing one of the main surfaces of the disc substrate 2. The ICP electrode 17 is disposed such that the inner surface of its ring is substantially identical to the inner surface of the chamber 1 adjacent to the ICP electrode 17. Thus, a particle get sheet (for example, a copper sheet) can be easily attached to the ICP electrode 17, and consequently, a CVD film can be prevented from adhering to the ICP electrode, and maintenance is easily performed. As shown in FIG. 3, the outside shape of the ICP electrode 17 is a ring shape of a one turn coil. As shown in FIG. 6, a distance 17a between the ICP electrode 17 and the inner surface of the chamber 1 is 5 mm or less (preferably, 3 mm or less and more preferably 2 mm or less). The reason why the distance is set at 5 mm or less as described above is that, since an abnormal discharge does not occur across the gap of 5 mm or less and thus the adherence of the CVD film does not occur, it is possible to prevent the CVD film from adhering to the inner surface of the chamber 1 in the gap.

Likewise, an ICP electrode 18 that is the same as the ICP electrode 17 is disposed on a side (right side of FIG. 1) facing the other main surface of the disc substrate 2.

The output terminals A of the ICP electrodes 17 and 18 are electrically connected to RF plasma power supplies 7 and 8 through matching boxes (MB) 4 and 5, respectively. The output terminals B of the ICP electrodes 17 and 18 are electrically connected to an earth power supply not shown) through a variable capacitor (not shown). As the RF plasma power supplies 7 and 8, high-frequency power supplies having a frequency of 1 MHz to 27 MHz are preferably used. Thus, it is possible to easily diffuse an ionized raw material gas. In the present embodiment, 500 W high-frequency power supplies having a frequency of 13.56 kHz are used.

As shown in FIG. 1, the plasma CVD device has a gas discharge ring 28; this gas discharge ring 28 is disposed at an end of the chamber 1 positioned on the opposite side of the disc substrate 2 with respect to the ICP electrode 17. As shown in FIGS. 2 and 4, this gas discharge ring 28 includes a gas introduction port 28a, a ring-shaped path 28b connected to the gas introduction port 28a, a plurality of gas discharge ports 28c connected to the ring-shaped path 28b and a ring-shaped outlet port 28d connected to these gas discharge ports 28c. The gas discharge ring 28 has an earth potential. A gas supply mechanism is connected to the gas discharge ring 28.

The width of the ring-shaped path 28b is 5 mm or less (preferably, 3 mm or less and more preferably 2 mm or less). The gas discharge ports 28c are equally spaced in the ring-shaped path 28b, and evenly discharge gas in a radial direction of the ring. Specifically, the gas introduced by the gas supply mechanism through the gas introduction port 28a passes through the ring-shaped path 28b, and is evenly discharged from the gas discharge ports 28c in the radial direction of the ring. The discharged gas is evenly introduced into the chamber 1 through the ring-shaped outlet port 28d. The reason why the width of the ring-shaped path 28b is set at 5 mm or less is that, since a discharge does not occur in the ring-shaped path whose width is 5 mm or less and thus the adherence of the CVD film does not occur, it is possible to prevent the CVD film from adhering to the gas discharge ring 28.

Likewise, a gas discharge ring 29 having the same configuration is disposed at an end of the chamber 1 positioned on the opposite side of the disc substrate 2 with respect to the ICP electrode 18; the gas supply mechanism is connected to the gas discharge ring 29.

As shown in FIG. 1, the gas supply mechanism has raw material gas supply sources 30 and 31; a liquid of C₆H₅CH₃ is stored in the raw material gas supply sources 30 and 31. The raw material gas supply sources 30 and 31 have heating means (not shown) for heating them. The raw material gas supply sources 30 and 31 are connected to valves 32 and 33; the valves 32 and 33 are connected to valves 34 and 35 through pipes. The valves 34 and 35 are connected to mass flow controllers 36 and 37; the mass flow controllers 36 and 37 are connected to valves 38 and 39. The valves 38 and 39 are connected to the gas introduction ports of the gas discharge rings 28 and 29 through pipes. The liquid of C₆H₅CH₃ is heated by the heating means, and heaters 30a and 31a are wound around the pipes so that the vaporized raw material gas is prevented from being cooled while being introduced into the chamber 1.

The gas supply mechanism also has an Ar gas source and an O₂ gas source. The Ar gas source is connected to valves 40 and 41 through pipes; the valves 40 and 41 are connected to mass flow controllers 42 and 43. The mass flow controllers 42 and 43 are connected to valves 44 and 45; the valves 44 and 45 are connected to the gas discharge rings 28 and 29 through pipes. The O₂ gas source is connected to valves 46 and 47 through pipes; the valves 46 and 47 are connected to mass flow controllers 48 and 49. The mass flow controllers 48 and 49 are connected to valves 50 and 51; the valves 50 and 51 are connected to the gas introduction ports of the gas discharge rings 28 and 29 through pipes.

The plasma CVD device includes heaters 26 and 27; the heaters 26 and 27 are disposed inside the gas discharge rings 28 and 29. Since the heaters 26 and 27 are earth electrodes (anode electrodes) themselves, they are heated earth electrodes. The heaters 26 and 27 are electrically connected to power supplies 52 and 53 for heaters; the power supplies 52 and 53 for heaters are electrically connected to temperature controllers 54 and 55. These temperature controllers 54 and 55 measure the temperatures of the earth electrodes, and, based on the measurement results, the power supplies 52 and 53 for heaters adjust the heating power of the heaters 26 and 27.

When a DLC film is formed on the disc substrate 2, the DLC film also adheres to the earth electrodes. When the DLC film, which is an insulating material, covers the earth electrodes, which are a conducting material, a discharge does not occur between the earth electrodes and the ICP electrodes 17 and 18; even if a discharge occurs, a discharge occurs between the ICP electrodes and the chamber, a plasma swells, and resultantly the density of the plasma is reduced. However, when the heaters 26 and 27 themselves are used as the earth electrodes and the earth electrodes are heated to 450° C. or more, the DLC film adhering to the earth electrodes can be changed into graphite, which is a conducting material, and resultantly a discharge can be produced between the earth electrodes and the ICP electrodes 17 and 18. In other words, when the DLC film is formed on the disc substrate 2 while the earth electrodes are being heated to 450° C. or more, the DLC film adhering to the earth electrodes can be constantly changed into graphite, and thus a discharge between the earth electrodes and the ICP electrodes 17 and 18 can be continuously kept for a long period of time. Moreover, since the gas discharge rings are disposed near the heaters, molecules within the gas are heated by the heat of the heaters, and thus chemical reactions easily occur, and resultantly the number of particles can be reduced.

As shown in FIG. 2, the plasma CVD device includes a cylindrical plasma wall 24; the plasma wall 24 is disposed between the disc substrate 2 and the ICP electrode 17. The plasma wall 24 is provided so as to surround the space between the ICP electrode 17 and the disc substrate 2. The plasma wall 24 is electrically connected to a float potential. Specifically, as shown in FIG. 1, the plasma wall 24 is electrically connected to a ground potential through a switch 22; the switch 22 is in a state where the plasma wall 24 is not connected to the earth power supply.

The plasma wall 24 is set at a float potential as described above, and thus the plasma wall 24 can prevent a discharge between the ICP electrode 17 and the disc substrate 2 from occurring. Hence, when the raw material gas ionized by a discharge between the ICP electrode 17 and the anode electrode is guided to the disc substrate 2, the CVD film can be prevented from adhering to the plasma wall 24; even if the CVD film adheres to the plasma wall 24, the CVD film becomes soft such that the CVD film is unlikely to be detached from the plasma wall 24, and thus it is possible to reduce the number of particles.

Specifically, since a small number of ions are present within the plasma wall 24, it is possible to prevent a high density CVD film from adhering to the plasma wall 24. Moreover, the ions can move straight to the disc substrate 2 without being trapped by an earth electric field owing to the plasma wall 24 at the float potential. When the plasma wall 24 is set at the earth potential, a plasma occurs within the plasma wall; when the plasma wall is set at the float potential, it is possible to prevent the plasma from being generated.

Likewise, a plasma wall 25 is disposed between the disc substrate 2 and the ICP electrode 18.

Film-thickness correction plates 56 and 57 are attached to end portions of the plasma walls 24 and 25 on the side of the disc substrate 2, and these film-thickness correction plates 56 and 57 are disposed on both sides of the disc substrate 2. When the disc substrate 2 is disc-shaped, the CVD film tends to be formed thick on its outer circumferential portion; the outer circumferential portion is a region in which, when films are simultaneously formed on both sides of the disc substrate 2, plasmas on the right and left sides affect each other. The film-thickness correction plates 56 and 57 are doughnut-shaped to cover the outer circumferential portion of the disc-shaped disc substrate 2, and function to make uniform the thickness of the CVD film formed over the entire disc substrate 2.

The plasma CVD device includes ring-shaped magnets 58 and 59; as shown in FIGS. 1 and 2, the magnets 58 and 59 are disposed between the earth electrodes (the heaters 26 and 27) and the ICP electrodes 17 and 18. As shown in FIG. 5, the magnets 58 and 59 are ring-shaped to cover the outside of the chamber 1. The plasma is concentrated in a magnetic field generated by the magnets 58 and 59, and this allows the plasma to easily be ignited. In addition, the magnetic field generated by the magnets 58 and 59 allows a high density plasma to be generated, and thus it is possible to enhance an ionization efficiency.

A method of forming the CVD film on the disc substrate 2 with the plasma CVD device shown in FIG. 1 will now be described below.

The disc substrate 2 is first held within the chamber 1, and the chamber 1 is vacuum-evacuated with the vacuum evacuation mechanism. In the present embodiment, the disc substrate 2 is used as the substrate to be film-formed; instead of the disc substrate, as the substrate to be film-formed, for example, a Si wafer, a plastic substrate or one of various electronic devices can be used. The plastic substrate can be used because it can form a film at a low temperature (for example, at a temperature of 150° C. or less).

Then, the raw material gas is fed into the chamber 1. As the raw material gas, one of various raw material gases can be used; for example, a hydrocarbon gas, a silicon compound gas or oxygen can be used. As the silicon compound gas, hexamethyldisilazan or hexamethyldisiloxane (also collectively referred to as an HMDS) which is easy to handle and enables film formation at a low temperature is preferably used.

When the chamber 1 has a predetermined pressure, a high frequency electric power of 300 W having a frequency of 13.56 MHz is supplied to the ICP electrodes 17 and 18 by the RF plasma power supplies 7 and 8, and a high frequency electric power of 500 W having a frequency of 100 to 500 kHz (preferably 250 kHz) is supplied by the RF acceleration power supply 6 to the disc substrate 2 through the matching box 3. Thus, a discharge between the ICP electrodes 17 and 18 and the anode electrodes occurs, and the plasma is generated near the ICP electrodes 17 and 18. Consequently, it is possible to ionize the raw material gas. Here, since the magnetic field is generated by the magnets 58 and 59 near the ICP electrodes 17 and 18, the density of the plasma can be increased with this magnetic field, and the ionization efficiency can be enhanced. The raw material gas thus ionized is guided to the disc substrate 2, and the CVD film can be formed on both sides of the disc substrate 2. Instead of the RF acceleration power supply 6, the DC acceleration power supply 9 may be used to supply a DC power to the disc substrate 2.

A thin film thus formed is a film that has a main component of, for example, carbon or silicon. One example of the film that has a main component of carbon includes the DLC film; one example of the film that has a main component of silicon includes an SᵢO₂ film. The raw material gas used when the SᵢO₂ film is formed includes an HMDS and oxygen.

According to the first embodiment described above, since the ICP electrodes (cathode electrodes) 17 and 18 are used instead of filament cathode electrodes made of tantalum as in the conventional technology, even if oxygen gas is introduced into the chamber 1, it is possible to prevent the failure to use the cathode electrodes. Thus, it is possible to use a raw material gas containing oxygen gas. It is also possible to introduce oxygen gas into the chamber 1 and perform plasma cleaning with oxygen ashing. Thus, it is possible to remove dirt within the chamber 1, which makes it easy to perform its maintenance.

In the first embodiment described above, the magnets 58 and 59 are disposed substantially in the middle between the earth electrodes (the heaters 26 and 27) and the ICP electrodes 17 and 18, thus the plasma generation portion of the device can trap the plasma, and consequently it is possible to increase the density of the plasma. In this way, it is possible to enhance the ionization of the raw material gas, which makes it easy to generate, for example, SᵢO₂.

In the first embodiment described above, the inner wall of the chamber 1 located between each of the gas discharge rings 28 and 29 and the disc substrate 2 is free from projections and recesses. Thus, it is possible to make more uniform the plasma used when the CVD film is formed. Furthermore, when the plasma cleaning is performed, it is possible to easily remove the CVD film adhering to the inside of the chamber 1.

A method for producing a magnetic recording medium with the plasma CVD device shown in FIG. 1 will now be described.

A substrate to be film-formed obtained by forming at least a magnetic layer on a nonmagnetic substrate is first prepared, and the substrate to be film-formed is disposed within the chamber 1. Then, within the chamber 1, the raw material gas is turned into a plasma state by a discharge between the ICP electrode and the earth electrode, and this plasma is accelerated and caused to collide against the surface of the substrate to be film-formed. Thus, on the surface of the substrate to be film-formed, a protective layer whose main component is carbon is formed.

Although, in the first embodiment described above, the heaters 26 and 27 for heating the earth electrodes (anode electrodes) are provided, in addition to the heaters, a cooling mechanism for cooling part (for example, a portion near an O-ring) of the earth electrode with water or the like may be further provided. With this cooling mechanism, it is possible to prevent part of the earth electrode from being overheated.

Although, in the first embodiment described above, the ring-shaped magnets 58 and 59 are disposed, in addition to the magnets, a cooling mechanism for cooling the magnets with water or the like may be further provided. The magnets are cooled with the cooling mechanism, thus it is possible to maintain a constant temperature of the magnets when the CVD film is formed, and resultantly the magnetic force can be stabilized.

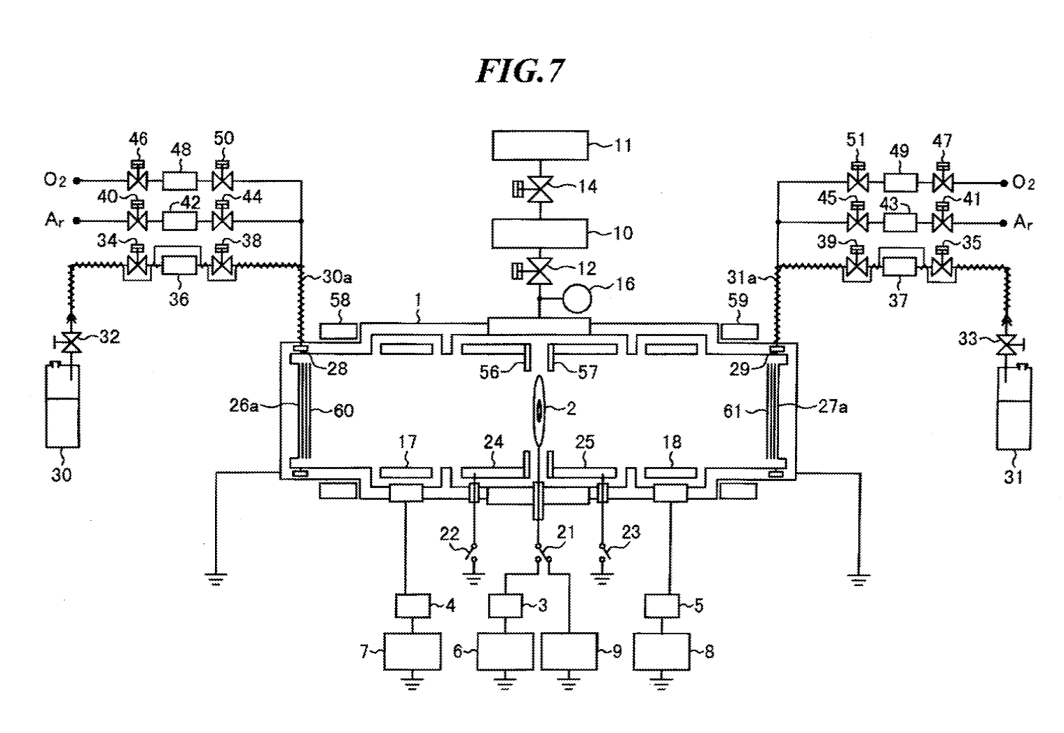

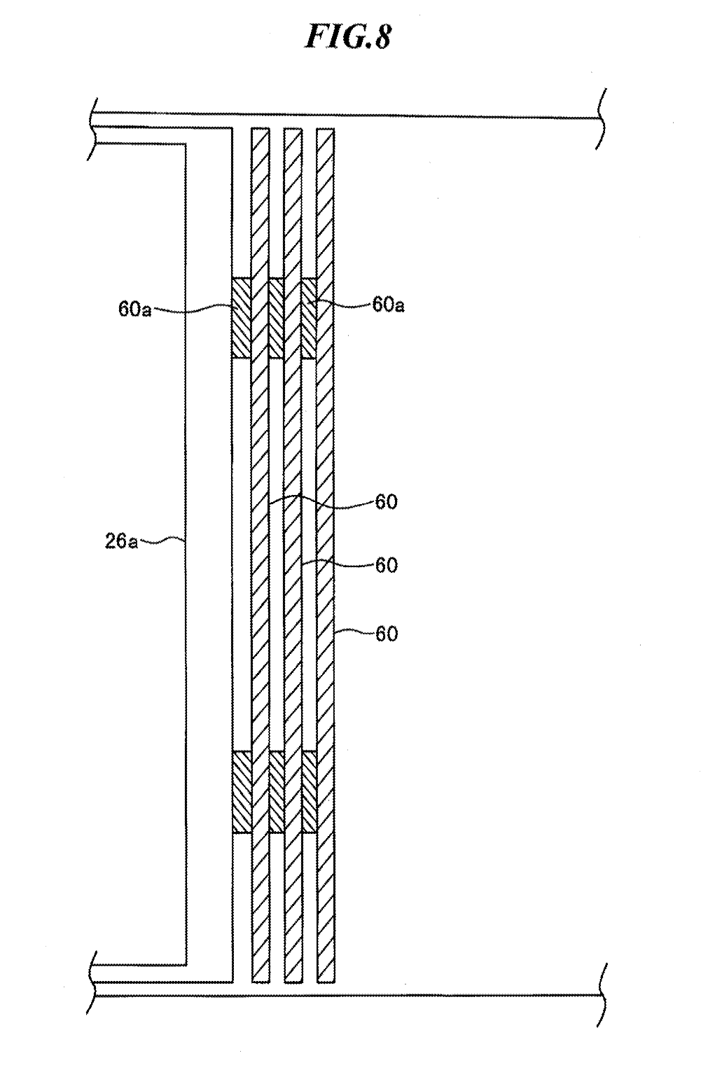

FIG. 7 is a schematic view showing the overall configuration of a plasma CVD device according to a second embodiment of the present invention; FIG. 8 is an enlarged cross-sectional view of a hidden earth electrode shown in FIG. 7. The same parts as in FIG. 3 are identified with like symbols, and only parts different from FIG. 1 will be described.

Although the plasma CVD device of the first embodiment shown in FIG. 1 has the heaters 26 and 27 that also serve as the earth electrodes (anode electrodes), the power supplies 52 and 53 for heaters and the temperature controllers 54 and 55, the plasma CVD device of the second embodiment shown in FIG. 7 has hidden earth electrodes 60 and 61 (see FIG. 8) instead of the heaters 26 and 27, the power supplies 52 and 53 for heaters and the temperature controllers 54 and 55. The hidden earth electrodes 60 and 61 are one or more earth electrodes disposed near anode electrodes (earth electrodes) 26a and 27a; the one or more earth electrodes 60 and 61 and the anode electrodes 26a and 27a are spaced 5 mm or less (preferably 3 mm or less and more preferably 2 mm or less) apart facing each other using spacers 60a. The reason why they are spaced 5 mm or less apart facing each other is that, since the CVD film does not adhere to the surfaces of the electrodes spaced 5 mm or less apart facing each other, it is possible to prevent a discharge from being stopped due to that the CVD film adheres to the entire surfaces of the anode electrodes and the hidden earth electrodes, and it is possible to constantly maintain a stable discharge.

In the second embodiment described above, the same effects as in the first embodiment can be obtained.

Conditions for and results of forming the DLC (diamond like carbon) film with the plasma CVD device shown in FIG. 1 will now be described.

(Film Formation Conditions)

Gas: C₇H₈

Gas flow rate: 2.8 sccm

Outside magnetic field: 100 G (gauss)

ICP power supply: 300 W

Pulse bias: 450V

Pressure: 0.15 Pa

(Film Formation Results)

Film formation rate: 0.5 nm/minute

Knoop hardness (HK): 2916 (average value at five points)

Distribution of the DLC film: Good

(Knoop Hardness Scale Measurement Method)

Device: Minute hardness scale DMH-2 type made by Matsuzawa Seiki Co., Ltd.

Indenter: Vertex angles 172.5°, 130° Rhombus diamond square pyramid indenter

Load: 5 g

Load period: 15 seconds

Measurement points: Any five points on a sample

The present invention is not limited to the embodiments described above; many modifications are possible without departing from the gist of the present invention. For example, it is possible to change the RF plasma power supplies 7 and 8 to other plasma power supplies; examples of the other plasma power supplies include a power supply for microwave, a power supply for DC discharge, a pulse-modulated high-frequency power supply, a pulse-modulated power supply for microwave and a pulse-modulated power supply for DC discharge.

In the first and second embodiments described above, the output terminals A of the ICP electrodes 17 and 18 are electrically connected to the RF plasma power supplies 7 and 8 through the matching boxes (MB) 4 and 5, respectively, and the output terminals B of the ICP electrodes 17 and 18 are electrically connected to the earth power supply (not shown) through the variable capacitor (not shown), respectively. This configuration may be changed to any one of first to third variations described below, and it may be practiced.

(First Variation)

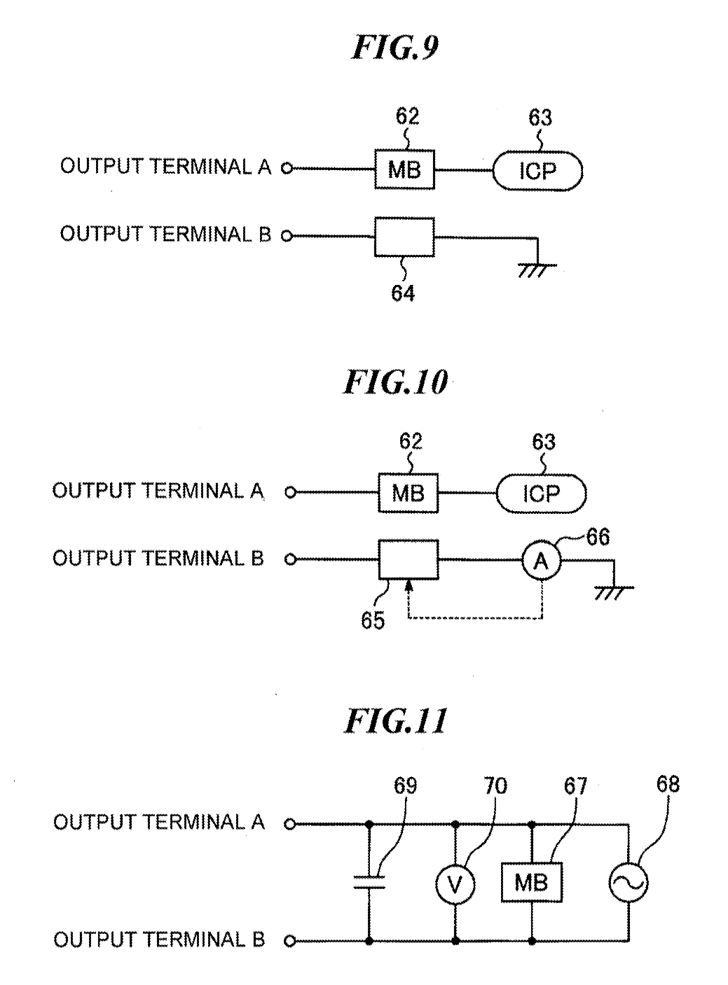

FIG. 9 is a schematic view illustrating a first variation.

The respective output terminals A of the ICP electrodes 17 and 18 are electrically connected to an ICP power supply 63 through a matching box 62. The respective output terminals B of the ICP electrodes 17 and 18 are connected to a ground potential through a resonance capacitor 64. The resonance capacitor 64 has a capacitance that satisfies resonance conditions or the permissible operation range of the resonance conditions for the frequency of a high-frequency current output from the ICP power supply 63 and the inductance of the ICP electrodes 17 and 18.

Specifically, when the ICP power supply 63 supplies a high-frequency current having, for example, a frequency of 13.56 MHz to the ICP electrode through the matching box 62, the high-frequency current flows through the ICP electrode under the resonance conditions. Hence, the high-frequency current is the maximum current at the above-mentioned frequency. When the maximum high-frequency current flows through the ICP electrode, a large magnetic field is generated from the ICP electrode, and this magnetic field generates a large electric field inside the ICP electrode. Consequently, it is possible to generate an extremely high-density inductively-coupled plasma of the raw material gas inside the ICP electrode and in the vicinity thereof.

In other words, the important feature of the first variation is that, since a resonance circuit (ICP circuit) is configured in which a resonance capacitor is connected in series to the ICP electrode, and constants (an inductance of the ICP electrode, a frequency of the high-frequency current and a capacitance of the resonance capacitor) are selected so that resonance occurs at a frequency used, technological advantages such as (1) and (2) shown below are acquired.

(1) The floating capacitance of the ICP electrode is extremely small, it is possible to largely ignore a capacitive coupling discharge (CCD) occurring at the beginning of a discharge and a plasma is produced by an inductive coupling discharge (ICD). Hence, the plasma is stable and highly dense.

(2) Although the magnetic coupling of the ICP electrode and the generated plasma is strong, the Q value (to be described later) of the resonance circuit described above is low, the error tolerance for the circuit constants is high and the circuit is a simple circuit, the circuit stably operates and is easy to use.

When the capacitance of the resonance capacitor is set within the permissible operation range of the resonance conditions, since, if a high-frequency current is supplied to the ICP, electrode, the high-frequency current flows through the ICP electrode under conditions that are close to the resonance conditions, the high-frequency current is brought close to the maximum current. Therefore, in this case, it is also possible to generate a high density inductively-coupled plasma of the raw material gas inside the ICP electrode and in the vicinity thereof. The resonance conditions and the permissible operation range of the resonance conditions will be described below.

When the frequency of the ICP power supply 63 is f (unit: Hz), the inductance of the ICP electrode is L (unit: H (henry)) and the capacitance of the resonance capacitor is C (unit: F (farad)), in order to achieve the resonance conditions, it is necessary to satisfy equation (1) below.

ω=2πf=(LC)^{-1/2} (1)

Equation (2) below is given by equation (1) above.

C=1/(2πf)²L (2)

Thus, in order to achieve the resonance conditions, the capacitance C of the resonance capacitor needs to be set at 1/(2πf)²L.

Taking the natural logarithm of both sides of equation (1) above gives:

In2π+Inf=−1/2(InL+InC)

Differentiating both sides gives:

δf/f=−1/2(δL/L+δC/C)

When the absolute values of both sides are calculated, the right-hand side is positive.

Thus, if δL/L=δC/C=0.1, δf/f=0.1. This corresponds to the Q value 10.

Therefore, the permissible error of the ICP electrode and the capacitor is 10% at the maximum.

When, as in the above calculation, the ICP electrode and the plasma are sufficiently coupled to each other, it is probably possible to acquire a sufficiently large error of the inductance of the ICP electrode and a sufficiently large error of the capacitance of the resonance capacitor, and it is probably possible to acquire a total permissible error of about 10%. Hence, when the error of 10% is equally distributed to the ICP electrode and the resonance capacitor 64, it is probably possible to acquire the permissible error of 10% of the resonance capacitor. Therefore, the capacitance C of the resonance capacitor 64 can also be set within the range of equation (3) below; more preferably, it is set within the range of equation (4) below.

0.9/(2πf)²L≦C≦1.1/(2πf)²L (3)

0.95/(2πf)²L≦C≦1.05/(2πf)²L (4)

A description will be given substituting specific values into equations (2) and (4) above. For example, when f=13.56 MHz and L=1 μH, the capacitance of the resonance capacitor is preferably set within a range between 131.1 pF and 144.9 pF inclusive, and the capacitance of the resonance capacitor is more preferably set at 138 pF. This type of resonance capacitor is easy to obtain.

$$\begin{matrix}C = 1 / {( 6.28 \times 13.56 \times E 6 )}^{2} \times 1 \times E - 6 \\ = 1.38 \times {10}^{- 10} ( farad ) \\ = 138 pF\end{matrix}$$

$$C ( lower limit value ) = 138 \times 0.95 = 131.1 pF$$

$$C ( upper limit value ) = 138 \times 1.05 = 144.9 pF$$

According to the first variation described above, when the frequency of the ICP power supply 63 is f and the inductance of the ICP electrode is L, the capacitance C of the resonance capacitor is set at 1/(2πf)²L or set within 0.9/(2πf)²L≦C≦1.1/(2πf)²L. Thus, when the high-frequency current is supplied to the ICP electrode, it is possible to generate resonance. Hence, the high-frequency current value becomes close to the highest, and it is possible to stably generate a high-density inductively-coupled plasma.

(Second Variation)

FIG. 10 is a schematic view illustrating a second variation.

The second variation differs from the first variation in that, instead of the resonance capacitor, a variable capacitor 65 is mounted, and that an ammeter 66 for measuring high-frequency currents flowing through the ICP electrodes 17 and 18 is added.

Specifically, the variable capacitor 65 is connected to the output terminals B of the ICP electrode, the ammeter 66 is connected to the variable capacitor 65 and the ammeter 66 is connected to a ground potential. The values of the high-frequency currents flowing through the ICP electrodes 17 and 18 and measured by the ammeter 66 are fed back to the variable capacitor 65, and the variable capacitor 65 is controlled as follows by an unillustrated control portion.

When the raw material gas is introduced into the chamber 1, the high-frequency current is supplied to the ICP electrode, the inductively-coupled plasma of the gas is generated under the resonance conditions or within the permissible operation range of the resonance conditions and thus the CVD film formation processing is performed, depending on conditions such as the pressure within the chamber 1 and the type of raw material gas, the ICP electrode and the atmosphere therearound are closely coupled to each other, and thus the equivalent inductance of the ICP electrode including the inductance of the gas around the ICP electrode or the like may be varied. In this case, the resonance conditions are also varied. Hence, a current flowing through the ICP electrode is measured with the ammeter 66 during the processing, and variations in the resonance conditions are detected from the current value thus measured. Then, the detection result is fed back to the variable capacitor 65, and the capacitance of the variable capacitor 65 is adjusted so that actual values become close to the resonance conditions. This prevents actual values from deviating from the resonance conditions or the permissible operation range of the resonance conditions, which makes it possible to perform high-density plasma processing more stably.

(Third Variation)

FIG. 11 is a schematic view illustrating a third variation.

A matching box 67 is connected in parallel to the ICP electrodes 17 and 18. An ICP power supply 68 that applies a high-frequency voltage is connected in parallel to the ICP electrode. A resonance capacitor 69 is connected in parallel to the ICP, electrode. A voltmeter 70 is connected in parallel to the ICP electrode. The resonance capacitor 69 has a capacitance that satisfies the resonance conditions or the permissible operation range of the resonance conditions for the frequency of the high-frequency voltage output from the ICP power supply 68 and the inductance of the ICP electrode.

Specifically, when the ICP power supply 68 supplies the high-frequency voltage having a frequency of, for example, 13.56 Hz to the ICP electrodes 17 and 18 through the matching box 67, the high-frequency voltage is applied across the ICP electrode under the resonance conditions, and thus the high-frequency voltage becomes the maximum voltage at the frequency. The maximum high-frequency voltage is applied to the ICP electrode, and thus a large magnetic field is generated from the ICP electrode, and this magnetic field generates a large electric field inside the ICP electrode. Consequently, it is possible to generate an extremely high density inductively-coupled plasma of the raw material gas inside the ICP electrode and in the vicinity thereof.

### LIST OF REFERENCE SYMBOLS

1: Chamber, 2: Disc substrate, 3 to 5: Matching box, 6: RF acceleration power supply, 7 and 8: RF plasma power supply, 9: DC acceleration power supply, 10: TMP, 11: Dry pump, 12 and 14: Valve, 16: Vacuum gauge, 17 and 18: ICP electrode, 21 to 23: Switch, 24 and 25: Plasma wall, 26 and 27: Heater, 28 and 29: Gas discharge ring, 30 and 31: Raw material gas supply source, 32 to 35, 38 to 41, 44 to 47, 50 and 51: Valve, 36, 37, 42, 43, 48 and 49: Mass flow controller, 52 and 53: Power supply thyristor for heater, 54 and 55: Temperature controller, 56 and 57: Film thickness correction plate, 58 and 59: Magnet, 60 and 61: Hidden earth electrode, 60a: Spacer, 62 and 67: Matching box, 63 and 68: ICP power supply, 64 and 69: Resonance capacitor, 65: Variable capacitor, 66: Ammeter, 70: Voltmeter

1-15. (canceled)

16. A plasma CVD device comprising:
a chamber;
a ring-shaped electrode disposed within said chamber;
a first high-frequency power supply electrically connected to said ring-shaped electrode;
a gas supply mechanism that supplies a raw material gas into said chamber;
an evacuation mechanism that evacuates said chamber;
a substrate to be film-formed disposed within said chamber so as to face said ring-shaped electrode;
a second high-frequency power supply or a DC power supply electrically connected to said substrate to be film-formed;
an earth electrode disposed within said chamber on the opposite side of said substrate to be film-formed so as to face said ring-shaped electrode;
a plasma wall disposed within said chamber and provided so as to surround a space between said ring-shaped electrode and said substrate to be film-formed; and
a magnet disposed between said ring-shaped electrode and said earth electrode,
wherein said plasma wall is set at a float potential.

17. The plasma CVD device of claim 16,
wherein said ring-shaped electrode is disposed such that an inner surface of the ring is substantially identical to an inner surface of said chamber adjacent to the ring-shaped electrode.

18. The plasma CVD device of claim 16,
wherein a distance between said ring-shaped electrode and the inner surface of said chamber facing an outer surface of the ring is 5 mm or less.

19. The plasma CVD device of claim 16,
wherein the maximum width of a path through which said gas supply mechanism supplies gas into said chamber is 5 mm or less, and said path is set at an earth potential.

20. The plasma CVD device of claim 16,
wherein a frequency output from said second high-frequency power supply is lower than a frequency output from said first high-frequency power supply.

21. The plasma CVD device of claim 16,
wherein said first high-frequency power supply has a frequency of 1 MHz to 27 MHz, and said second high-frequency power supply has a frequency of 100 kHz to 500 kHz or less.

22. The plasma CVD device of claim 16, further comprising heating means that heats said earth electrode.

23. The plasma CVD device of claim 22,
wherein the gas supplied by said gas supply mechanism into said chamber is heated by said heating means.

24. The plasma CVD device of claim 22,
wherein said earth electrode is heated by said heating means to a temperature of 300° C. to 500° C.

25. The plasma CVD device of claim 16,
wherein a supply port supplied by said gas supply mechanism into said chamber is ring-shaped to surround said earth electrode.

26. The plasma CVD device of claim 16,
wherein said earth electrode is composed of a plurality of earth electrodes, and a distance between said plurality of earth electrodes facing each other is 5 mm or less.

27. A method of producing a thin film with the plasma CVD device of 16, said method comprising the steps of:
disposing a substrate to be film-formed within said chamber; and
turning said raw material gas into a plasma state by a discharge between said ring-shaped electrode and said earth electrode to form a thin film on a surface of said substrate to be film-formed.

28. The method of producing a thin film according to claim 27,
wherein a main component of said thin film is carbon or silicon.

29. A method of producing a magnetic recording medium with a plasma CVD device of claim 16, said method comprising the steps of:
disposing within said chamber a substrate to be film-formed obtained by forming at least a magnetic layer on a nonmagnetic substrate;
turning said raw material gas into a plasma state by a discharge between said ring-shaped electrode and said earth electrode within said chamber; and
accelerating the plasma and causing it to collide against a surface of said substrate to be film-formed to form a protective layer whose main component is carbon.
